(19) United States
(12) Patent Application Publication
(10) Pub. No.: US 2006/0189108 A1
(43) Pub. Date: Aug. 24, 2006

(54) Suppressing formation of metal silicides on semiconductor surfaces

(75) Inventor: Meng Tao, Colleyville, TX (US)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: BOARD OF REGENTS, THE UNIVERSITY OF TEXAS SYSTEM, AUSTIN, TX (US)

(21) Appl. No.: 11/360,139

(22) Filed: Feb. 23, 2006

Related U.S. Application Data
(60) Provisional application No. 60/655,383, filed on Feb. 23, 2005.

(51) Int. Cl. H01L 21/20

(52) U.S. Cl. 438/584

(57) ABSTRACT

The present invention provides for compositions and methods of modifying a semiconductor structure, the structure including a semiconductor material, silicon, or germanium. The methods include modifying at the atomic scale at least one surface of the structure and forming a low-reactivity surface, contacting the at least one surface with at least one metal, and annealing the at least one metal to the at least one surface at a temperature ranging from room temperature to at least about 750 degrees Centigrade. The methods prevent the formation of high resistance phases of a metal silicide. The methods also prevent metal silicide formation at temperatures below at least about 500 degrees Centigrade and provide for only low resistance phases of the metal silicide at temperatures above at least about 500 degrees Centigrade. The methods further provide for compositions with improved performance.

### CROSS-REFERENCES TO RELATED APPLICATIONS

This application claims the benefit of U.S. Provisional Patent Application No. 60/655,383, filed Feb. 23, 2005.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of Grant No. ESC-0322762 awarded by the National Science Foundation.

### BACKGROUND OF THE INVENTION

The present invention relates generally to the field of semiconductor interface engineering and in particular to compositions and methods for preparing such compositions, the methods capable of modifying a surface of a semiconductor and of suppressing the formation of high resistance phases of metal silicides on such semiconductor surfaces.

Metal silicides have become more widely used for the application of electronic devices, particularly because metal silicides offer lower resistivities than polysilicon. Unfortunately, when such materials are scaled down to the micrometer and nanometer levels, there is a difficulty in achieving low resistance.

While metal silicides exhibit significantly lower resistance as compared with polysilicon, the use of metal suicides is limited because current fabrication techniques may promote the formation of a silicide phase with high resistance. In addition, some fabrication techniques are actually deleterious to the metal silicide layer. For example, thermal cycling promotes thermal degradation of the gate resistance on metal-oxide semiconductor field-effect transistors, transistors that include a metal silicide layer.

Therefore, in applying metal silicides to microelectronic and nanoelectronic structures, the issue of performance and reliability is of great importance. Electronic structures containing one or more metal suicides must show low resistance to achieve the best performance and must maintain their structural integrity in order to prevent breakdown and failure of the structure and the device it comprises. As such, there remains a need for improving the fabrication of such electronic structures using metal silicides in order to improve their performance and reliability.

### SUMMARY OF THE INVENTION

The present invention solves many problems associated with current limitations in the use of metal suicides for electronic structures.

Generally and in one form, the present invention provides for an improved method of modifying the surface of a semiconductor structure in order to prevent or suppress the formation of high-resistance phases of at least one metal silicide. The method may be applied using any metal silicide, including near-noble metal silicides, transition metal silicides, and rare-earth metal silicides. The method also applies to silicide formation on silicon-on-insulator structures. The method uses annealing temperatures ranging from room temperature up to 750 degrees Centigrade. The method includes atomic-scale engineering of at least one surface of the semiconductor structure, the structure comprising a semiconductor material, such as silicon and germanium.

More specifically, one form of the present invention is a method of modifying a semiconductor structure comprising the steps of modifying at the atomic scale at least one surface of the semiconductor structure, contacting the at least one surface with a metal and annealing the metal to the at least one surface at a temperature ranging from room temperature to at least about 500 degrees Centigrade, wherein the method prevents the formation of high resistance phases of a metal silicide. The modification creates a low-reactivity surface on the semiconductor structure to improve performance and prevent breakdown and failure of the semiconductor structure. In addition, the method prevents metal silicide formation at temperatures below at least about 500 degrees Centigrade and provides only low resistance phases of the metal silicide at temperatures above at least about 500 degrees Centigrade.

In another form, the invention provides for a method of modifying a semiconductor structure comprising the steps of modifying at the atomic scale at least one surface of the semiconductor structure, wherein modifying the at least one surface includes passivating the surface with a passivating agent, contacting the at least one surface with a metal, and annealing the metal to the at least one surface at a temperature ranging from room temperature to at least about 750 degrees Centigrade. The method prevents the formation of high resistance phases of a metal silicide. Further, the method prevents metal silicide formation at temperatures below at least about 500 degrees Centigrade and provides for only low resistance phases of the metal silicide at temperatures above about 500 degrees Centigrade

The passivating agent is typically a Group VI compound, such as sulfur, selenium, and tellurium. Techniques for passivating the surface may include those known to one skilled in the art, such as is chemical vapor deposition, molecular beam epitaxy, atomic layer deposition, and wet chemistry. The semiconductor structure is a microelectronic or nanoelectronic structure, including any semiconductor material, such as silicon and germanium. The structure may be a silicon (100) wafer.

In yet another form, the present invention provides for compositions prepared by methods of the present invention. With the present invention, the prepared compositions exhibit improved performance, reliability and structural integrity.

There are several advantages with the present invention. One advantage is that the methods provided herein may be used for any electronic structure comprising a semiconductor materials, such as silicon and germanium. The semiconductor structure may exhibit be n-type or p-type and may be doped at any level with any dopant. Applicable structures also include nanoelectronic devices employed in integrated circuits (e.g., metal-oxide-semiconductor field-effect transistors and bipolar junction transistors). Another advantage is that any metal capable of forming a metal silicide may be used with the present invention.

Methods of the present invention are efficient, time-saving and cost-saving because the structures provided herein provide improved performance and structural integrity. Methods and compositions that are provided for may be used in integrated circuitry and in any industry or for any applications requiring integrated circuits, including telecommunications, optics, security devices, computing, data storage, signal processing, home electronics, as examples.

Those skilled in the art will further appreciate the above-noted features and advantages of the invention together with other important aspects thereof upon reading the detailed description that follows in conjunction with the drawings.

### BRIEF DESCRIPTION OF SEVERAL VIEWS OF THE DRAWINGS

For more complete understanding of the features and advantages of the present invention, reference is now made to the detailed description of the invention along with the accompanying figures, wherein:

FIG. 1 depicts a representative example of a conventional process to form a metal silicide in which FIG. 1A is an initial silicon structure; FIG. 1B is the structure following deposition of a thin metal layer on the silicon structure; and FIG. 1C is the structure following thermal processing of the metal/silicon structure using a temperature between room temperature and about 750 degrees Centigrade after which a metal silicide is formed;

FIG. 2 depicts representative examples of sheet resistance for one metal silicide formed using a conventional process;

FIG. 3 depicts a representative example of suppressing the formation of high-resistance phases of a metal silicide in accordance with one aspect of the present invention in which FIG. 3A is an initial semiconductor structure; FIG. 3B depicts passivation with a passivating agent; FIG. 3C depicts deposition of a thin metal layer; and FIG. 1D depicts thermal processing of the metal/semiconductor structure using a temperature between room temperature and about 500 degrees Centigrade after which no metal silicide is formed; and

FIG. 4 depicts representative examples of sheet resistance in the absence and presence of a passivating agent in accordance with one aspect of the present invention.

### DETAILED DESCRIPTION OF THE INVENTION

Although making and using various embodiments of the present invention are discussed in detail below, it should be appreciated that the present invention provides many inventive concepts that may be embodied in a wide variety of contexts. The specific aspects and embodiments discussed herein are merely illustrative of ways to make and use the invention, and do not limit the scope of the invention.

In the description which follows like parts may be marked throughout the specification and drawing with the same reference numerals, respectively. The drawing figures are not necessarily to scale and certain features may be shown exaggerated in scale or in somewhat generalized or schematic form in the interest of clarity and conciseness.

Metal silicides are used in advanced integrated circuits as electrical contacts for semiconductor structures typically comprising semiconductor materials, such as silicon and germanium. Low resistance is a key requirement for metal silicide contacts. Metal silicides are compounds formed by metals and silicon. Many metal silicides exhibit metallic conduction behaviors and have attracted attention because of their low and metal-like resistivity, high temperature stability, and high electromigration resistance.

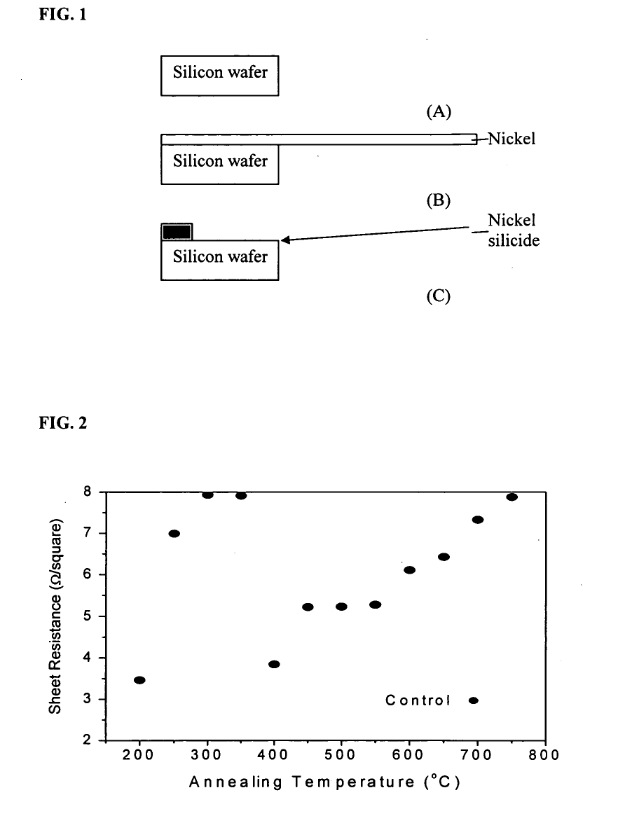

A conventional method to form a metal silicide on a silicon structure is shown in FIG. 1. Typically the method includes depositing a thin layer of at least one metal on at least one surface of a semiconductor structure that includes silicon (FIG. 1B). The metal/silicon structure is then heated, typically using high temperatures (several hundreds of degrees above room temperature), and the metal silicide is formed between the metal and silicon (FIG. 1C).

For electrical contacts, low resistance is a key requirement. With metal suicides, the resistance is, in part, a function of the fabrication technique used to create the metal silicide. Using nickel as an example, the phases of nickel silicide formed at temperatures from room temperature to about 400 degrees Centigrade exhibit a high resistance as compared to the phases of nickel silicide formed at temperatures between 400 and 750 degrees Centigrade. Metal silicides also exhibit different phases with different resistivities. Again, using nickel as an example, nickel monosilicide (NiSi) is the desired phase for use with most electronic structures because it provides low resistivity, particularly for electrical contacts to a source, drain and gate of metal-oxide-semiconductor field-effect transistors with dimensions less than 100 nanometers. High resistance phases of nickel silicide are formed at relatively low annealing temperatures below 400 degrees Centigrade, while low resistance nickel monosilicide is formed above 400 degrees Centigrade. While more difficult to prepare, it is the low-resistance phases of nickel silicide and other metal silicides that are used in electronic structures (e.g., advanced integrated circuits) as electrical contacts to semiconductor silicon.

In principle, on semiconductor surfaces, the formation of high-resistance phases of a metal silicide, such as nickel silicide, can be suppressed by avoiding the temperature ranges that form them. For example, one can avoid temperatures from room temperature to about 400 degrees Centigrade to suppress high-resistance nickel silicide phases. Practically, however, it is nearly impossible to avoid this temperature range because a metal/semiconductor structure is subjected to repeated thermal cyclings (heating to above 400 degrees Centigrade and cooling to room temperature) during the manufacturing process to create an integrated circuit. The result is that following the thermal cyclings, high-resistance phases of the metal silicide are formed.

FIG. 2 shows a representative sheet resistance versus annealing temperature profile for a silicon wafer in which the metal, nickel, was used to form the metal silicide layer via the conventional method. In conventional systems, high resistance nickel silicide is formed between temperatures of 200 and 400 degrees Centigrade. At temperatures between 400 degrees and 600 degrees Centigrade, low resistance nickel silicide is typically formed. As a result, the high temperature range is the typical range used for processing nickel silicide; however, temperatures less than 400 degrees can not be avoided with current manufacturing processes, and thus high resistance nickel silicide is usually formed.

The present invention provides for a method of eliminating the formation of high-resistant suicides by modifying a semiconductor structure on at least one of its surfaces, the modification being capable of suppressing the formation of high resistance phases of any metal silicide at one surface at annealing temperatures typically used to prepare high resistance phases of the metal silicide. Some chemical aspects of the present invention were recently communicated and are herein incorporated by reference (see Tao, M, et al. Suppression of silicon (001) surface reactivity using a valence-mending technique, Solid State Communications 2004:132; 89-92).

With the present invention, the formation of high resistance phases of metal silicide are suppressed at temperatures that range from room temperature up to at least about 750 degrees Centigrade. The method comprises atomic-scale engineering of at least one surface of a semiconductor materials, such as the silicon (100) surface. Transmission electron microscopy, X-ray photoelectron spectroscopy, four-point probe and X-ray diffraction are examples of some of the techniques used to verify the suppression of high resistance phases of a metal silicide using methods as set forth with the present invention.

In general, the present invention modifies a semiconductor surface structure on at least one of its surfaces preventing the formation of high-resistance phases of metal silicide on the at least one surface of the semiconductor structure. A metal silicide layer is provided for by contacting a modified surface of a semiconductor structure with a metal and heating the modified surface to a temperature that may range from room temperature up to at least about 750 degrees Centigrade. At this referenced temperature range, the formed layer includes either the unreacted metal or lower-resistance phases of the metal silicide.

The present invention modifies a semiconductor structure at at least one of its surfaces by reducing the chemical reactivity of the semiconductor surface and by terminating dangling bonds on the semiconductor surface. Typically, the silicon surface comprises a silicon (100) surface. Termination of dangling bonds on the silicon surface is provided for by the addition of a passivating agent. Passivating agents are typically Group VI compounds, including sulfur, selenium, and tellurium. Following the reduction of chemical reactivity at the at least one surface of the semiconductor structure, the at least one surface (now a low-reactivity semiconductor surface) is contacted by a metal. The metal may include a near-noble metal, transition metal, and rare-earth metal. Upon annealing, the metal may or may not react with the low-reactivity semiconductor surface. Annealing temperatures range from room temperature to at least about 750 degrees Centigrade. At temperatures below about 500 degrees, there is an absence of any metal silicide. At temperatures above about 500 degrees Centigrade, only lower-resistance phases of a metal silicide are created. As such, with the present invention, no high-resistance phases of the metal silicide are formed at the low-reactivity silicon surface.

An example of metal silicide preparation in accordance with one aspect of the present invention is shown in FIG. 3. Here, a monolayer of a passivating agent is applied to the surface of a semiconductor structure, typically a silicon (100) surface which can be p-type or n-type with a wide range of doping levels from 10¹² to 10²⁰ cm⁻³ (FIGS. 3A and 3B). The passivating agent may be sulfur, selenium, tellurium, or any Group VI compound. Following passivation, a thin layer of a metal is deposited on the passivated surface, as shown in FIG. 3C. This is followed by heating the semiconductor structure to a temperature, typically one ranging from room temperature to at least about 500 degrees Centigrade (FIG. 3D). After the application of heat, metal silicide, including high resistance phases, is suppressed.

With the present invention, the passivated surface of the semiconductor structure exhibits low chemical reactivity. Addition of a passivating agent reduces the chemical reactivity on the surface of the semiconductor structure by terminating dangling bonds. Passivation prevents further chemical reactions even following the application of a metal to this low-reactivity surface while heated to a representative (typically, room temperature to about 500 degrees Centigrade. Above the representative temperature, high resistance phases of a metal silicide are formed. As such, the method suppresses and prevents formation of high-resistances phases of the metal silicide and, instead, provides for the formation of only low-resistance phases of the metal silicide.

In one example, a 500 Angstrom layer of nickel was deposited on one of two samples. Each sample was an identical n-type silicon (100) wafer with a doping level of approximately 10¹⁵ cm⁻³ phosphorous. The first wafer was cleaned by submerging it into a water solution of 2% hydrofluoric acid for 30 seconds. The first wafer was then loaded into a molecular beam epitaxy system. A monolayer of selenium was deposited on the first wafer surface, and the first wafer was unloaded and exposed to air. The second wafer was cleaned by submerging it into a water solution of 2% hydrofluoric acid for 30 seconds. The second wafer did not undergo passivation, therefore there was no selenium or other passivating agent applied to the surface.

The above is a representative example. With the present invention, the semiconductor structure may exhibit any conduction (e.g., n-type, p-type) at any doping level provided by any dopant. The semiconductor structure or wafer may be cleaned by any method known to one skilled in the art. The cleaning time may also vary as needed. Passivation techniques include those known to one of skill in the art, such as chemical vapor deposition, atomic layer deposition, molecular beam epitaxy, or wet chemistry. Such alterations require no undue experimentation on the part of one skilled in the art.

The first and second wafers were subsequently loaded into an electron-beam evaporator. The chamber was pumped down to about 10⁻⁶ Torr. 500 Angstrom nickel was evaporated onto the first and second wafers and the two wafers were then removed from the electron-beam evaporator. Here, nickel is used as a representative metal. Any metal capable of forming a metal silicide may be used. The thickness of the metal may be thicker or thinner, as required for its application. In addition, chamber pressure of the evaporator may be higher or lower, as required. Such alterations require no undue experimentation on the part of one skilled in the art.

The first and second wafers were cut into pieces, each piece heated to a temperature from between 200 and 750 degrees Centigrade in a chamber filled with one atmosphere of nitrogen for about one minute. After cooling down, each piece was removed from the chamber. The chamber gas may be nitrogen, helium, argon, or other acceptable gases known to one skilled in the art and the chamber pressurized as required.

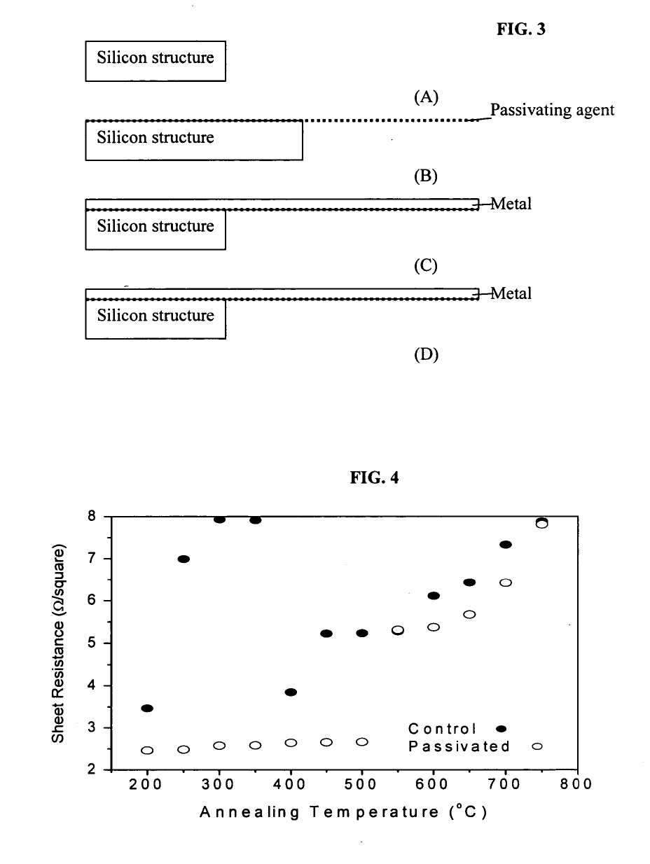

Sheet resistances of all pieces were measured after heat treatment at different temperatures using a four-point probe. Sheet resistances as a function of heat treatment temperature are shown in FIG. 4 with filled circle representing the nonpassivated (control) wafer and unfilled circles representing the passivated wafer.

Samples of the present invention in which the metal was nickel and the passivating agent was selenium typically exhibited a number of characteristics following heat treatment. For example, the sheet resistance of the passivated wafer remained at approximately 2.5 Ω/square at temperatures ranging from room temperature to 500 degrees Centigrade. On the other hand, for the same temperature range, the sheet resistance of the control wafer increased to almost 8 Ω/square. At temperatures ranging from about 550 to 750 degrees, the passivated wafer exhibited a lower sheet resistance than the control wafer. When the passivated structure was heated to above 500 degrees Centigrade, a low-resistance phase nickel silicide was formed.

Accordingly, the present invention provides for a method of modifying a semiconductor structure comprising the steps of modifying at the atomic scale at least one surface of a silicon structure, wherein in the silicon structure is a silicon (100) wafer and wherein modifying the at least one surface includes passivating the surface with a passivating agent, contacting the at least one surface with a metal, wherein the metal is selected from the group consisting of a near-noble metal, transition metal, and rare-earth metal, annealing the metal to the at least one surface at a temperature ranging from room temperature to about 750 degrees Centigrade, wherein the method prevents metal silicide formation at temperatures below at least about 500 degrees Centigrade and provides for only low resistance phases of the metal silicide at temperatures above the at least about 500 degrees Centigrade.

Importantly, the present invention prevents and eliminates silicide formation on a semiconductor surface when temperatures are between room temperature and at least about 500 degrees Centigrade. In addition, the present invention provides for only low resistance silicide above this temperature of at least about 500 degrees Centigrade. This is in contract to conventional processes that create high-resistance silicides on semiconductor surfaces when temperatures are below 400 degrees Centigrade and promote low-resistance silicides only when temperatures exceed 400 degrees Centigrade.

Additional objects, advantages and novel features of the invention as set forth in the description, will be apparent to one skilled in the art after reading the foregoing detailed description or may be learned by practice of the invention. The objects and advantages of the invention may be realized and attained by means of the instruments and combinations particularly pointed out here.

What is claimed is:

1. A method of modifying a semiconductor structure comprising the steps of:
modifying at least one surface of the semiconductor structure;
contacting the at least one surface with at least one metal; and
annealing the at least one metal to the at least one surface at a temperature ranging from ambient temperature to about 750 degrees Centigrade,
wherein the formation of high resistance phases of a metal silicide is prevented.

2. The method of claim 1, wherein the at least one metal is selected from the group consisting of a near-noble metal, transition metal, rare-earth metal, and combinations thereof.

3. The method of claim 1, wherein modifying the at least one surface includes passivating the surface with a passivating agent.

4. The method of claim 3, wherein the passivating agent is selected from the group consisting of sulfur, selenium, tellurium, and Group VI compounds.

5. The method of claim 3, wherein passivating the surface is selected from the group consisting of chemical vapor deposition, atomic layer deposition, molecular beam epitaxy and wet chemistry.

6. The method of claim 1, wherein the semiconductor structure is selected from the group consisting of a semiconductor material, silicon, and germanium.

7. The method of claim 1, wherein the semiconductor structure is a microelectronic structure or nanoelectronic structure.

8. The method of claim 11, wherein the step of modifying creates a low-reactivity surface on the at least one surface.

9. The method of claim 1, wherein the method prevents metal silicide formation at temperatures below at least about 500 degrees Centigrade.

10. The method of claim 1, wherein the method provides only low resistance phases of the metal silicide at temperatures above at least about 500 degrees Centigrade.

11. A method of modifying a semiconductor structure comprising the steps of:
modifying at the atomic scale at least one surface of the semiconductor structure, wherein modifying the at least one surface includes passivating the surface with a passivating agent;
contacting the at least one surface with at least one metal;
annealing the at least one metal to the at least one surface at a temperature ranging from ambient temperature to about 750 degrees Centigrade,
wherein the formation of high resistance phases of a metal silicide is prevented.

12. The method of claim 11, wherein the at least one metal is selected from the group consisting of a near-noble metal, transition metal, rare-earth metal, and combinations thereof.

13. The method of claim 11, wherein the passivating agent is selected from the group consisting of sulfur, selenium, tellurium, and Group VI compounds.

14. The method of claim 11, wherein passivating the surface is selected from the group consisting of chemical vapor deposition, atomic layer deposition, molecular beam epitaxy and wet chemistry.

15. The method of claim 11, wherein the method prevents metal silicide formation at temperatures below at least about 500 degrees Centigrade and provides only low resistance phases of the metal silicide at temperatures above the at least about 500 degrees Centigrade.

16. The method of claim 11, wherein the semiconductor structure is selected from the group consisting of a semiconductor material, silicon, and germanium.

17. A composition prepared by the method of claim 1.

18. The composition of claim 17, wherein the semiconductor structure of claim 1 is selected from the group consisting of a semiconductor material, silicon, and germanium.

19. The composition of claim 17, wherein the at least one metal of claim 1 is selected from the group consisting of a near-noble metal, transition metal, rare-earth metal, and combinations thereof.

20. The composition of claim 17, wherein the composition is an integrated circuit.
